(19) United States
(12) Patent Application Publication
(10) Pub. No.: US 2008/0006389 A1
(43) Pub. Date: Jan. 10, 2008

(54) Preventing burst-related hazards in microelectronic cooling systems

(76) Inventors: Ioan Sauciuc, Phoenix, AZ (US); Gregory M. Chrysler, Chandler, AZ (US); Je-Young Chang, Phoenix, AZ (US); Ravi Prasher, Phoenix, AZ (US)

Correspondence Address: INTEL CORPORATION;c/o INTELLEVATE, LLC, P.O. BOX 52050, MINNEAPOLIS, MN, 55402, US

(21) Appl. No.: 11/477,095

(22) Filed: Jun. 27, 2006

(51) Int. Cl. A23C 3/02; H01L 23/34

(52) U.S. Cl. 165/66; 257/714

(57) ABSTRACT

Devices and associated methods to prevent burst-related hazards by providing pressure relief in a microelectronic cooling system are generally described. In this regard, according to one example embodiment, a pump outlet line includes at least one pressure relief indentation to rupture along the indentation at a selected pressure to prevent burst-related hazards in a microelectronic cooling system.

### TECHNICAL FIELD

Embodiments of the present invention are generally directed to cooling systems and, more particularly, to devices and associated methods for preventing burst-related hazards in microelectronic cooling systems.

### BACKGROUND

Microelectronic devices generate heat as a result of the electrical activity of the internal circuitry. In order to reduce the damaging effects of this heat, thermal management systems have been developed to remove the heat. Microchannel heat exchangers and associated techniques are emerging as a cooling solution for faster, more powerful, and more densely packed microelectronic devices such as processors. The small dimensions of microelectronic cooling system components, for example in microchannel heat exchangers, may increase the likelihood of blockages and associated bursting hazards. A blockage in a pumped microelectronic cooling system may generate sufficient pressure to rupture components of the system causing damage to the equipment and/or users. Improved safety techniques are needed to reduce the hazards associated with potential blockages.

### BRIEF DESCRIPTION OF THE DRAWINGS

Embodiments of the present invention are illustrated by way of example, and not by way of limitation, in the figures of the accompanying drawings in which like reference numerals refer to similar elements and in which:

FIG. 1 is a schematic of an example microelectronic cooling system, according to but one example embodiment;

FIG. 2 is a cross-section view of an example pressure relief device for a microelectronic cooling system, according to but one example embodiment;

FIG. 3 is a schematic of a pressure relief by-pass line for a microelectronic cooling system, according to but one example embodiment;

FIG. 4 is a graph of the bursting pressure for Copper/Nickel tubing;

FIG. 5 is a flow chart of an example method for providing pressure relief in a microelectronic cooling system, according to but one example embodiment; and

FIG. 6 is a flow chart of another example method for providing pressure relief in a microelectronic cooling system, according to but one example embodiment.

### DETAILED DESCRIPTION

Embodiments of pressure relief devices for microelectronic cooling systems and corresponding methods are described herein. In the following description, numerous specific details are set forth to provide a thorough understanding of embodiments of the invention. One skilled in the relevant art will recognize, however, that the invention can be practiced without one or more of the specific details, or with other methods, components, materials, etc. In other instances, well-known structures, materials, or operations are not shown or described in detail to avoid obscuring aspects of the description.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

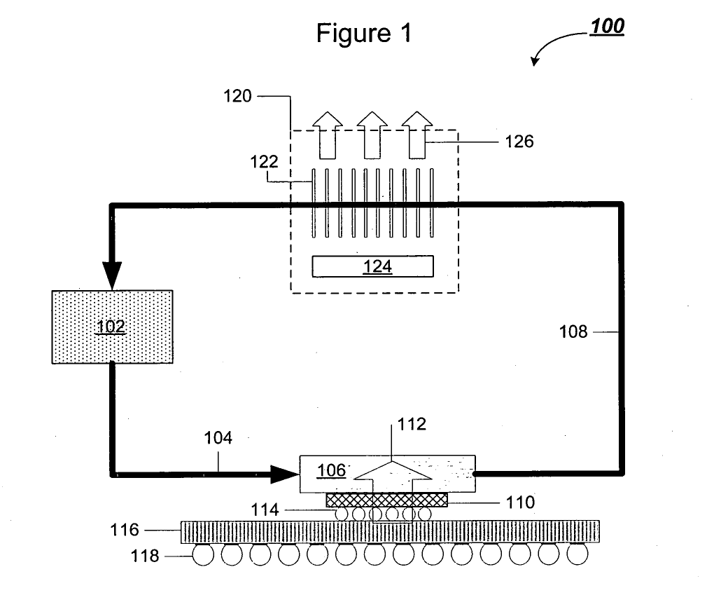

FIG. 1 provides a schematic of an example microelectronic cooling system, suitable for use in accordance with one embodiment. An example microelectronic cooling system 100 may include a pump 102, a pump outlet line 104, a heat exchanger 106, a pump inlet line 108, and a heat removal mechanism 120, each coupled as shown.

In one embodiment, microelectronic cooling system 100 may include a microelectronic device 110 thermally coupled with the heat exchanger 106. The microelectronic device 110 may or may not be activated. Heat 112 may be generated by electrical activity within the microelectronic device 110. The microelectronic device 110 may be electrically coupled with a substrate 116 via bumps 114. The substrate 116 may be further electrically coupled with external devices, components, or systems via an array of solder balls 118. In one embodiment, the microelectronic device 110 includes one or more integrated circuit die(s). In another embodiment, the microelectronic device 110 is coupled with one or more other devices, such as memory.

Microelectronic cooling system 100 may include a heat removal mechanism 120 coupled with the pump inlet line 108 to remove heat 126 from a working fluid. In one embodiment, a heat removal mechanism 120 may include fins 122 coupled with the pump inlet line 108 and a blower 124 such as a fan, for example, to move air across the fins 122 and remove heat 126 from the system. Fins 122 are intended to represent any feature that enhances heat transfer by increasing the surface area contact of the pump inlet line 108 with working fluid on the working fluid side (not illustrated) or with air on the air-side of the pump inlet line 108. Fins 122 can embody a variety of shapes and sizes. Fins 122 may be used to enhance heat transfer 126 without a blower 124. A blower 124 or similar device like a fan, for example, may increase the flow of air or another fluid across the fins 122 of the heat removal mechanism 120 to further enhance heat removal 126.

According to one embodiment, the working fluid may be a liquid coolant. A liquid coolant may be any suitable working liquid such as a solution comprising water, potassium formate, or combinations thereof, for example. The selection of a liquid coolant may be influenced by factors such as heat transfer ability, working fluid efficiency, and corrosiveness. Typical characteristics that may affect a coolant's heat transfer and working fluid effectiveness include specific heat, conductivity, and viscosity among others. Higher specific heat, higher conductivity, and lower viscosity may improve a coolant's ability to transfer heat and efficiently operate as a pump working fluid. These characteristics may allow for lower pressure drop and flow rate requirements from a pump for a given thermal resistance. Improved heat transfer and pump efficiency may save energy and effectively reduce the size and cost of the pump needed to provide sufficient heat removal.

In an embodiment, the coolant that moves between the heat removal mechanism 120 and the heat exchanger 106 may be designated ‘cold’ coolant, whereas the coolant that moves between the heat exchanger 106 and the heat removal mechanism 120 may be designated ‘hot’ coolant. ‘Cold’ is not intended to imply that the coolant is actually cold, although it may be. Rather, use of the term is relative to the ‘hot’ coolant, in that ‘cold’ coolant refers to the coolant before it has absorbed energy 112 generated by the microelectronic device 110 within the heat exchanger 106. Conversely, ‘hot’ is not intended to necessarily imply that the coolant is actually hot, although it may be. Rather, ‘hot’ coolant refers to the coolant after it has absorbed energy 112 generated by the microelectronic device 110 within the heat exchanger 106 and before passing through the heat removal mechanism 120. The words ‘hot’ and ‘cold’ when used in reference to the coolant generally describe the relative heat of the coolant as it is processed through the cooling system 100.

According to one embodiment, a pump 102, when actuated, moves cold coolant through a pump outlet line 104 into a heat exchanger 106, which transfers heat 112 generated by a microelectronic device 110 to the cold coolant. The cold coolant becomes hot coolant after it absorbs the generated energy 112. The pump 102 moves the hot coolant out of the heat exchanger 106 through a pump inlet line 108 into a heat removal mechanism 120, which may remove heat 126 from the hot coolant in a variety of ways. Some embodiments of the heat removal mechanism have already been described in more detail above.

The hot coolant becomes cold coolant after the heat 126 has been removed from the hot coolant in the heat removal mechanism 120. The pump 102 may circulate the cold coolant leaving the heat removal mechanism 120 back through the heat exchanger 106 to absorb more energy 112 generated by the microelectronic device 110. This process may be continuous. Alternatively, this process may be selectively enabled and disabled based on system or device conditions such as, for example, the temperature of microelectronic device 110 or a temperature difference between microelectronic device 110 and an ambient temperature. Additional and/or different conditions may also be used.

In one embodiment, a pump 102 moves a working fluid through a heat exchanger 106 and a heat removal mechanism 120. The pump may cycle the working fluid through the elements of the cooling system 100 continuously, periodically, or intermittently. Pumps that are generally used in accordance with embodiments described herein may comprise any one or more of an electromechanical (i.e.—microelectromechanical system or MEMS-based) or electro-osmotic pumps (i.e.—electric kinetic or “E-K” pumps). However, the pump is not limited to these types and may comprise gear, piston, peristaltic, sliding vane, and centrifugal technologies among others without deviating from the scope and spirit of the present invention. In an embodiment, pump 102 is a constant displacement pump. Types of constant displacement pumps may include gear, lobe, vane, centrifugal, and screw pumps. In an embodiment, pump 102 is selected from the group consisting of a gear, lobe, vane, centrifugal, and screw pump. In another embodiment, pump 102 is a gear pump.

Heat exchanger 106 may be any suitable heat exchanger for use in microelectronic cooling systems. For example, micro-channel, mezzo-channel or more conventional large gap channel heat exchangers could benefit from the controlled pressure release mechanisms that are introduced for microelectronic cooling systems.

Microchannel heat exchangers and associated techniques are emerging as an improved thermal solution for high-power, densely populated microelectronic devices 110 such as processors and other integrated circuit (IC) dies. One such embodiment employs a microchannel heat exchanger 106 in a single-phase liquid cooling system. A single-phase system may use a working fluid such as a coolant, or cooling solution, in the liquid phase for heat transfer. A single phase system may also use a gas as a working fluid. Another embodiment employs a microchannel heat exchanger in a dual-phase, liquid-vapor cooling system, wherein the coolant undergoes partial vaporization during the heat transfer process. In one embodiment, heat exchanger 106 is a microchannel heat exchanger. In another embodiment, heat exchanger 106 may be used in a single-phase liquid cooling system 100.

An increased possibility for high pressures may exist in cooling systems 100 incorporating a coolant that is pumped through a microchannel heat exchanger 106. The small dimensions of the microchannels may make the microchannels more susceptible to clogging. The blockage of pumped working fluid may cause elevated pressures within the system possibly resulting in a hazardous rupture.

Particles may be shed into the working fluid by system components and accumulate in the filter, lines, and/or channels of the cooling system 100. Moving parts within a pump 102, such as bearings, may shed particles that accumulate within the system and may clog the pump lines 104 or microchannels 106. Other sources of blockage may include operator error, kinks in lines, and particles introduced during assembly of the cooling system.

Constant displacement pumps (e.g. gear pump) with characteristics of high static pressure capability at a low flow rate have been considered for use in microelectronic cooling systems 100. A blockage in a system using such a pump to move coolant may produce pressures exceeding 7 atm. The implementation of safety devices into the microelectronic cooling system may prevent burst-related hazards to equipment and people.

The pressure relief devices and methods described in the remaining Figures may be incorporated into various embodiments and combinations of embodiments for a microelectronic cooling system 100 already described above.

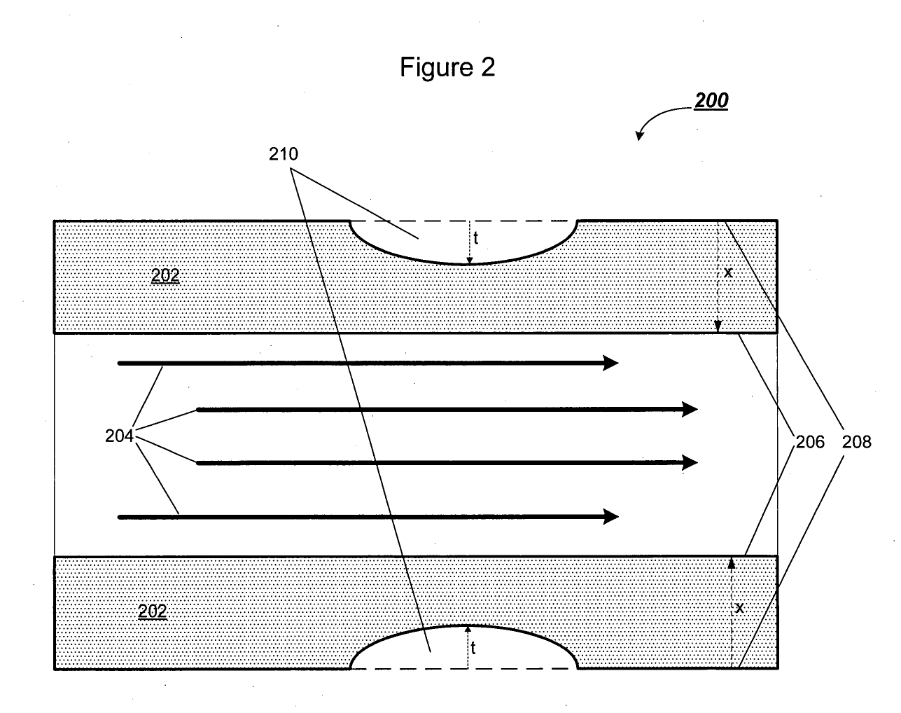

FIG. 2 is a cross-section view of an example pressure relief device 200 for a microelectronic cooling system 100, according to but one example embodiment. In one embodiment, pump outlet line 104, 202 may provide a pathway for a working fluid 204 from a pump 102. Pump outlet line 202 may have an inner surface 206 that may be in contact with a working fluid 204 and an outer surface 208 with a pressure relief indentation 210. Inner surface 206 may not necessarily be in contact with a working fluid 204, but may merely be an interior surface of a pump outlet line 202, forming an enclosure through which a working fluid may travel.

In an embodiment, indentation 210 may be designed to rupture along the indented portion 210 of pump outlet line 202 at a selected pressure to prevent burst-related hazards by providing pressure relief in a microelectronic cooling system before a significant internal pressure builds. A significant internal pressure may be a pressure that imperils equipment and/or people with a possible rupture in the microelectronic cooling system and may exceed about 100 kPa. A significant internal pressure may vary based on different applications, conditions, and materials.

The thickness, t, of indentation 210 may be selected so that the pump outlet line 202 between the indentation 210 and the inner surface 206 ruptures much before the allowable bursting pressure of other cooling system components 102, 104, 106, 108, 120. A larger indentation thickness, t, corresponds with a lower bursting pressure at indentation 210. In one embodiment, the selected rupture pressure for the indented 210 portion of the pump outlet line 202 is lower than the pressure required to rupture at least a portion of the pump outlet line 202 without the pressure relief indentation (e.g. the portion spanned by x). In another embodiment, the selected rupture pressure for the indentation 210 is about half the pressure required to rupture a non-indented portion of the pump outlet line 202 (e.g. the portion spanned by x).

Although indentation 210 is depicted as semi-oval in shape, various shapes and configurations are envisioned for pressure relief purposes. For example, a v-like notch could function as a pressure-relief indentation. A v-like notch may have a higher concentration of stress at the point of the notch than an indentation with only rounded features, corresponding with a lower bursting pressure for the v-like notch for the same indentation thickness, t. Other embodiments may include indentations 210 with rectangular profiles.

The indentation(s) 210 may be formed by any suitable method including cutting into the pump outlet line 202, etching away the pump outlet line material 202, or any other material removal process. The indentation(s) 210 may also be formed by a mold wherein the indentation is part of the mold for forming a pump outlet line.

The pump outlet line 104, 202 and inlet line 108 may be made of any suitable material, preferably a material that is compatible and non-corrosive with a chosen working fluid. Examples for a suitable material may include copper-nickel alloys, steel, and a variety of plastics.

More than one indentation 210 may be formed in the surface of a pump outlet line 202. For example, in one embodiment, a series of indentations may be formed resembling dimples or blind holes to weaken the structural integrity of a pump outlet line 202 to provide a selectively lower bursting pressure in the microelectronic cooling system. Such indentations 210 may circumnavigate the exterior of tubing 208 used for pump outlet 104, 202 and inlet 108 lines. In one embodiment, a pump outlet line 104, 202 made of substantially circular tubing has a continuous indentation 210 around the circumference of the exterior, forming a substantially annular groove in the exterior surface 208.

In an embodiment, at least one indentation 210 may be placed anywhere along the pump outlet line 104, 202 or the pump inlet line 108. The embodiments described herein for an indentation on a pump outlet line 104, 202 may also be applicable for the pump inlet line 108. An indentation 210 positioned as close as possible to the outlet side of the pump 102 in the pump outlet line 104, 202 may reduce the risks associated with a hazardous blockage. Any blockage that occurs downstream from the pump between the pump 102 and the pressure relief indentation 210 may not receive the benefit of the pressure relief indentation 210. Reducing the amount of tubing and number of components between the outlet side of the pump 102 and the pressure relief indentation 210 may reduce this risk. The pressure relief indentation 210 may be placed on the pump outlet line 104, 202 between the pump 102 and the heat exchanger 106 to reduce blockage risks associated the heat exchanger 106. In one embodiment, pressure relief indentation 210 may be placed on the pump outlet line 104, 202 between a pump 102 and a microchannel heat exchanger 106 to reduce risks associated with the small channels and dimensions of the microchannel heat exchanger 106. In one embodiment, a pressure relief indentation 210 is located on a portion of the outlet line 104, 202 as near the pump 102 as possible to reduce the risks associated with blockage in the system 100.

In an embodiment, a pressure relief device 200 for a microelectronic cooling system 100 includes a pump 102 coupled with a pump outlet line 104, 202, the pump outlet line 104, 202 including at least one pressure relief indentation 210 to rupture along the indentation at a selected pressure to prevent burst-related hazards in the microelectronic cooling system 100. In an alternative embodiment, a pressure relief device 200 also includes a heat exchanger 106 coupled to the pump outlet line 104, 202. Other embodiments include cooling system components such as a pump inlet line 108 to provide a pathway for the working fluid from the heat exchanger 106 to the pump 102 and a heat removal mechanism 120 thermally coupled to the pump inlet line 108 to remove heat 126 from the working fluid. Details of such components have been described in embodiments for FIG. 1 and may be incorporated with embodiments for the pressure relief device of FIG. 2.

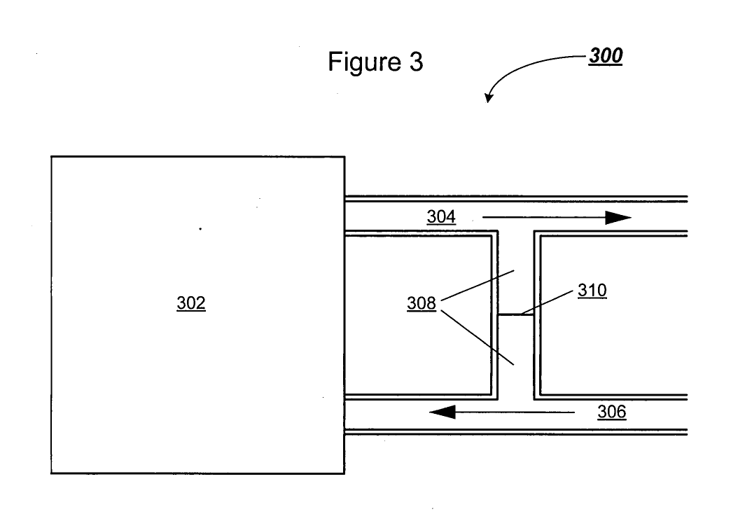

FIG. 3 is a schematic of a pressure relief by-pass line 308 for a microelectronic cooling system 300, according to but one example embodiment. In one embodiment, a pump 302 may be coupled to a pump outlet line 304 to provide a pathway for a working fluid from the pump 302. The pump 302 may also be coupled to a pump inlet line 306 to provide a pathway for a working fluid to the pump 302. A pressure relief by-pass line 308 with an internal bursting plate 310 may be coupled to the pump outlet 304 and pump inlet 306 lines to prevent burst-related hazards associated with a microelectronic cooling system 300.

In an embodiment, internal burst plate 310 may rupture at a selected pressure before the system 300 reaches elevated pressures that may be hazardous to equipment and/or people. Under normal flow and operating pressures (i.e.—without blockage), burst plate 310 may remain intact and the flow from the pump 302 may be delivered through a heat exchanger, for example. If a blockage occurs in a heat exchanger coupled to pump outlet line 304 and pump inlet line 306, for example, a rupture of internal burst plate 310 may provide an alternative path 308 for working fluid to flow to and from the pump 302. An internal burst plate 310 may be designed to rupture and release pressure from the pump outlet 304 to pump inlet 306 before other components rupture or burst.

A by-pass line 308 with internal burst plate 310 may provide the benefit of containing coolant if a blockage occurs. A rupture of the burst plate 310 may allow coolant to by-pass the blockage through the by-pass line 308 and continue to cycle through the pump 302. The flow of coolant may be contained within the pump 302, the pump outlet line 304, the by-pass line 308, and the pump inlet line 306. Thus, rupture of burst plate 310 may prevent an un-planned rupture of the pump inlet 306 or outlet line 304, for example, which could potentially spray coolant onto electrical components. A by-pass line 308 may also prevent a pump 302 from running dry during a blockage, preventing possible damage to the pump 302.

In an embodiment, burst plate 310 is a thin metal or plastic plate designed to break at a selected pressure. In one embodiment, the selected rupture pressure for the burst plate 310 is lower than the pressure required to rupture at least a portion of the pump outlet line 202 (e.g. the portion spanned by x). In another embodiment, the specified rupture pressure for the burst plate 310 is about half the pressure required to rupture a non-indented portion of the pump outlet line 202 (e.g. the portion spanned by x). Materials for burst plate 310 may be non-corrosive and compatible with a chosen working fluid for a cooling system 300. Materials for burst plate 310 are not limited to metals and plastics and may be any suitable material.

The location of the by-pass line 308 may affect the amount of risk associated with an uncontrolled rupture. For example, a by-pass line 308 that is coupled to the pump inlet 306 and outlet 304 lines closer to the pump 302 may decrease the risk of a hazardous rupture. A blockage that occurs downstream from the pump between the pump 302 and the location where the pump outlet line 304 couples with the by-pass line 308 may not receive the benefit of the by-pass line 308 with burst plate 310. Likewise, a blockage that occurs in the pump inlet line 306 between the pump 302 and the location where the pump inlet line 306 couples with the by-pass line 308 may not receive the pressure relief benefit of the by-pass line 308.

Reducing the amount of tubing and number of components between the pump 302 and the by-pass line 308 may reduce this risk. The by-pass line 308 may couple the pump outlet 304 with the pump inlet 306 line so that the flow by-passes other system elements, such as a heat exchanger for example, when a blockage occurs in the other system elements. An embodiment may include a similar arrangement 300 with a microchannel heat exchanger coupled to the pump inlet line 304 and pump outlet line 306 to remove heat from a microelectronic device. Such embodiment may avoid blockage risks associated with the small channels and dimensions of a microchannel heat exchanger, for example. In one embodiment, a by-pass line 308 is coupled with the outlet line 104, 304 as near the pump 302 as possible to reduce the risks associated with blockage in the system 300. In another embodiment, a by-pass line 308 is coupled with the inlet line 108, 306 as near the pump 302 as possible to reduce the risks associated with blockage in the system 300.

In an embodiment, a by-pass line 308 may be used in combination with at least one pressure relief indentation 210 on the pump inlet 108, 306 or outlet 104, 304 lines. The indentation 210 may rupture along the indentation at a selected pressure higher than the selected pressure required to rupture the burst plate 310. Indentation 210 may provide a back-up pressure relief mechanism in case the by-pass 308 arrangement fails.

Other embodiments include embodiments and combinations of embodiments already described for a microelectronic cooling system 100 and example pressure relief device 200.

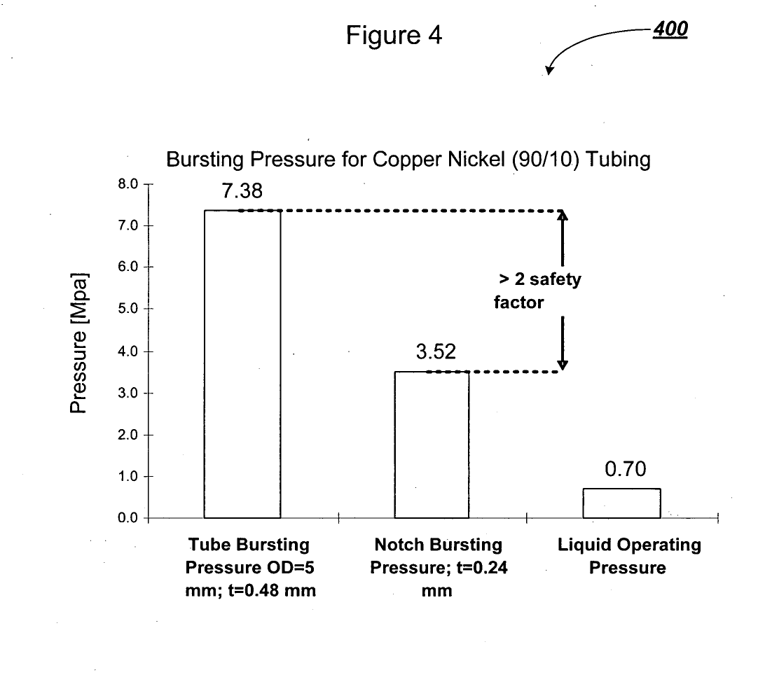

FIG. 4 is a graph 400 of the bursting pressure for Copper/Nickel (90/10) tubing, according to one example embodiment. Copper/Nickel (90/10) tubing may be an example material for use in pump inlet and outlet lines. Similar graphs may be obtained using other materials. Graph 400 compares the bursting pressure for regular tubing (thickness of tubing, t=0.48 mm) with “notched” or indented tubing (thickness of tubing at indentation, t=0.24 mm). Both are Copper/Nickel (90/10) tubing with an outer diameter (O.D.) of 5 mm. The tube bursting pressure refers to the pressure required to rupture a regular piece of Copper/Nickel (90/10) tubing with t=0.48 mm. The notch bursting pressure refers to the pressure required to rupture Copper/Nickel (90/10) tubing with an indentation-type feature where t=0.24 mm, similar in shape to that depicted in FIG. 2 indentation 210.

The tube bursting pressure for regular Copper/Nickel (90/10) tubing is about 7.38 MPa compared to a notch bursting pressure of about 3.52 MPa for Copper/Nickel (90/10) tubing with an indentation feature similar to that depicted in FIG. 2, indentation 210. Such example demonstrates that a pressure relief indentation (“notch”) may provide a safety factor greater than 2; the indentation may burst at less than half the pressure of regular tubing. For reference, the normal liquid operating pressure through Copper/Nickel (90/10) tubing, t=0.48 mm, O.D.=5 mm, may be about 0.70 MPa.

The embodiment illustrated in FIG. 4 is only one embodiment and is not limited to such materials or dimensions. Various parameters such as type of material or tubing dimensions and shapes may be modified for different purposes. For example, the tube diameter may be larger or smaller for a variety of reasons, and a different notch thickness may be suitable for a different-sized diameter.

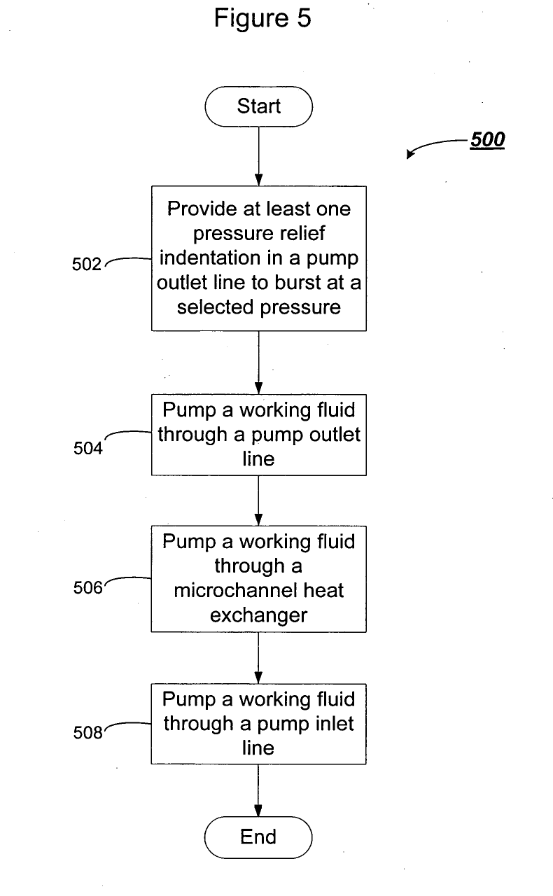

FIG. 5 is a flow chart of an example method for providing pressure relief in a microelectronic cooling system 500, according to but one example embodiment. A method for preventing burst-related hazards may include providing at least one pressure relief indentation in a pump outlet line to burst at a selected pressure 502, pumping a working fluid through a pump outlet line 504, pumping a working fluid through a heat exchanger 506, and pumping a working fluid through a pump inlet line 508. In an embodiment, the selected pressure is lower than the pressure required to rupture at least a portion of the pump outlet line without the pressure relief indentation (see the portion of 202 spanned by x, for example). In another embodiment, method 500 also includes providing a heat removal mechanism that is thermally coupled to the pump inlet line to remove heat from the working fluid.

Other embodiments for method 500 include embodiments and combinations of embodiments already described for cooling system 100, pressure relief indentation 200, by-pass arrangement 300, and graph 400.

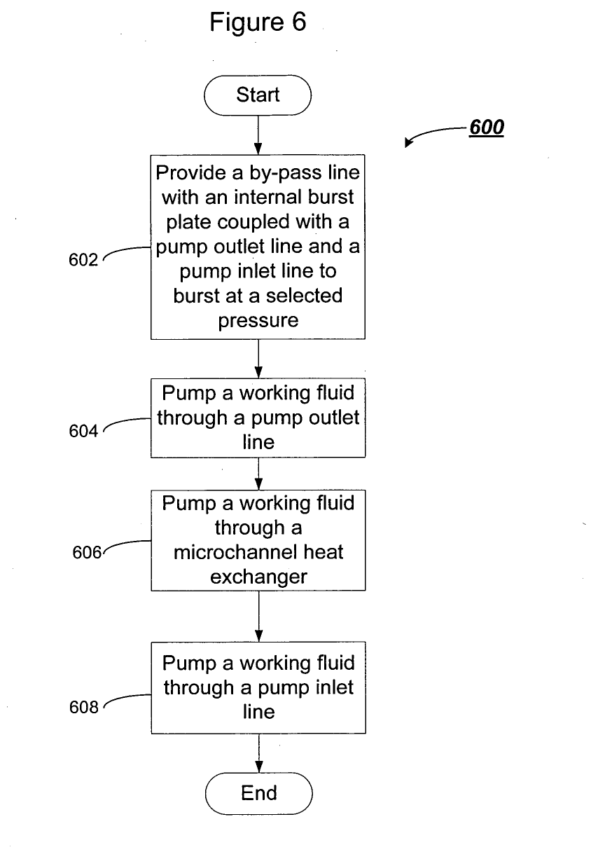

FIG. 6 is a flow chart of another example method for providing pressure relief in a microelectronic cooling system 600, according to but one example embodiment. A method 600 for preventing burst-related hazards may include providing a by-pass line with an internal burst plate coupled with a pump inlet line and a pump outlet line to burst at a selected pressure 602, pumping a working fluid through a pump outlet line 604, pumping a working fluid through a heat exchanger 606, and pumping a working fluid through a pump inlet line 608. In an embodiment, the selected pressure is lower than the pressure required to rupture at least a portion of the pump outlet line without the pressure relief indentation (see the portion of 202 spanned by x, for example). In another embodiment, method 600 also includes providing a heat removal mechanism that is thermally coupled to the pump inlet line to remove heat from the working fluid.

Other embodiments for method 600 include embodiments and combinations of embodiments already described for cooling system 100, pressure relief indentation 200, by-pass arrangement 300, and graph 400.

Although flowcharts 500 and 600 may depict the methods as being attached with unidirectional arrows, this is solely for ease of illustration purposes and does not necessarily limit or imply the ordering of the processes. For example, the process or processes depicted in the boxes may be continuous. The method may be part of a closed-loop or open-loop process. These steps may occur out of sequence or not at all.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. A pressure relief device for a microelectronic cooling system comprising:
a pump;
a pump outlet line coupled with the pump to provide a pathway for a working fluid from the pump, the pump outlet line comprising at least one pressure relief indentation to rupture along the indentation at a selected pressure to prevent burst-related hazards in the microelectronic cooling system; and
a heat exchanger coupled with the pump outlet line to remove heat from a microelectronic device.

2. A device according to claim 1, wherein the pump outlet line comprises substantially circular tubing with an interior surface and an exterior surface and wherein the pressure relief indentation is a substantially annular groove in the exterior surface of the pump outlet line.

3. A device according to claim 1, wherein the pressure relief indentation is located on a portion of the pump outlet line near the pump.

4. A device according to claim 1, wherein the selected pressure is lower than the pressure required to rupture at least a portion of the pump outlet line without the pressure relief indentation.

5. A device according to claim 1, wherein the heat exchanger is a microchannel heat exchanger thermally coupled with an integrated circuit die and the microchannel heat exchanger is part of a single-phase liquid cooling system.

6. A device according to claim 1, further comprising:
a pump inlet line to provide a pathway for the working fluid from the heat exchanger to the pump; and
a heat removal mechanism thermally coupled to the pump inlet line to remove heat from the working fluid.

7. A device according to claim 6, wherein the heat removal mechanism comprises:
fins thermally coupled to the pump inlet line to remove heat from the working fluid; and
a blower to move air across the fins and remove heat from the fins.

8. A device according to claim 1, wherein the pump is a constant displacement pump.

9. A device according to claim 8, wherein the pump is selected from the group consisting of a gear, lobe, vane, centrifugal and screw pump.

10. A pressure relief device for a microelectronic cooling system comprising:
a pump;
a pump outlet line coupled with the pump to provide a pathway for a working fluid from the pump;
a pump inlet line coupled with the pump to provide a pathway for the working fluid to the pump;
a by-pass line with an internal burst plate, the by-pass line coupled with the pump outlet line and the pump inlet line, the burst plate to rupture at a selected pressure to prevent burst-related hazards in the microelectronic cooling system; and
a heat exchanger coupled with the pump outlet line to remove heat from a microelectronic device.

11. A device according to claim 10, wherein the pump outlet line further comprises at least one pressure relief indentation located on the pump outlet line between the pump and the location where the pump outlet line is coupled with the by-pass line, the indentation to rupture along the indentation at a pressure higher than the selected pressure required to rupture the burst plate.

12. A device according to claim 10, wherein the by-pass line is coupled with the pump outlet line and inlet line near the pump.

13. A device according to claim 10, wherein the selected pressure is lower than the pressure required to rupture at least a portion of the pump outlet line.

14. A device according to claim 10, wherein the heat exchanger is a microchannel heat exchanger thermally coupled with an integrated circuit die and the microchannel heat exchanger is part of a single-phase liquid cooling system.

15. A device according to claim 10, further comprising:
a heat removal mechanism thermally coupled to the pump inlet line to remove heat from the working fluid.

16. A device according to claim 15, wherein the heat removal mechanism comprises:
fins thermally coupled to the pump inlet line to remove heat from the working fluid; and
a blower to move air across the fins and remove heat from the fins.

17. A device according to claim 10, wherein the pump is a constant displacement pump.

18. A device according to claim 17, wherein the pump is selected from the group consisting of a gear, lobe, vane, centrifugal and screw pump.

19. A method for relieving pressure in a microelectronic cooling system comprising:
pumping a working fluid through a pump outlet line coupled with a pump;
pumping the working fluid through a heat exchanger coupled with the pump outlet line to remove heat from a microelectronic device; and
providing at least one pressure relief indentation in the pump outlet line to rupture along the indentation at a selected pressure, to prevent burst-related hazards in the microelectronic cooling system.

20. A method according to claim 19, wherein the pump outlet line comprises substantially circular tubing with an interior surface and an exterior surface and wherein the pressure relief indentation is a substantially annular groove in the exterior surface of the pump outlet line.

21. A method according to claim 19, wherein the pressure relief indentation is located on a portion of the pump outlet line near the pump.

22. A method according to claim 19, wherein the selected pressure is lower than the pressure required to rupture at least a portion of the pump outlet line without the pressure relief indentation.

23. A method according to claim 19, wherein the heat exchanger is a microchannel heat exchanger thermally coupled with an integrated circuit die and the microchannel heat exchanger is part of a single-phase liquid cooling system.

24. A method according to claim 19, further comprising:
pumping the working fluid through a pump inlet line coupled with the heat exchanger and the pump, the pump inlet line to provide a pathway for the working fluid from the heat exchanger to the pump; and
providing a heat removal mechanism thermally coupled to the pump inlet line to remove heat from the working fluid.

25. A method according to claim 24, wherein providing a heat removal mechanism comprises:
providing fins thermally coupled to the pump inlet line to remove heat from the working fluid; and
providing a blower to move air across the fins and remove heat from the fins.

26. A method according to claim 19, wherein the pump is a constant displacement pump.

27. A system according to claim 26, wherein the pump is selected from the group consisting of a gear, lobe, vane, centrifugal and screw pump.

28. A method for relieving pressure in a microelectronic cooling system comprising:
pumping a working fluid through a heat exchanger, the working fluid being delivered to the heat exchanger via a pump outlet line coupled with a pump and the heat exchanger and the working fluid being delivered from the heat exchanger to the pump via a pump inlet line coupled with the heat exchanger and the pump; and
providing a by-pass line with an internal burst plate, the by-pass line coupled with the pump outlet line and the pump inlet line, the burst plate to rupture at a selected pressure to prevent burst-related hazards in the microelectronic cooling system.

29. A method according to claim 28, wherein the pump outlet line comprises at least one pressure relief indentation located on the pump outlet line between the pump and the location where the pump outlet line is coupled with the by-pass line, the indentation to rupture along the indentation at a pressure higher than the selected pressure required to rupture the burst plate.

30. A method according to claim 28, wherein the by-pass line is coupled with the pump outlet line near the pump.

31. A method according to claim 28, wherein the selected pressure is lower than the pressure required to rupture at least a portion of the pump outlet line.

32. A method according to claim 28, wherein the heat exchanger is a microchannel heat exchanger thermally coupled with an integrated circuit die and the microchannel heat exchanger is part of a single-phase liquid cooling system.

33. A method according to claim 28, further comprising:
providing a heat removal mechanism thermally coupled to the pump inlet line to remove heat from the working fluid.

34. A method according to claim 33, wherein providing the heat removal mechanism comprises:
providing fins thermally coupled to the pump inlet line to remove heat from the working fluid; and
providing a blower to move air across the fins and remove heat from the fins.

35. A method according to claim 28, wherein the pump is a constant displacement pump.

36. A method according to claim 35, wherein the pump is selected from the group consisting of a gear, lobe, vane, centrifugal and screw pump.

37. A pressure relief system for microelectronic cooling comprising:
a pump;
a pump outlet line coupled with the pump to provide a pathway for a working fluid from the pump, the pump outlet line comprising at least one pressure relief indentation to rupture along the indentation at a selected pressure to prevent burst-related hazards in the microelectronic cooling system;
a heat exchanger coupled with the pump outlet line; and
a microelectronic device thermally coupled with the heat exchanger.

38. A system according to claim 37, wherein the microelectronic device is an integrated circuit die and the heat exchanger is a microchannel heat exchanger used as part of a single-phase liquid cooling system.

39. A system according to claim 38, wherein the integrated circuit die is further coupled with memory.

40. A pressure relief system for microelectronic cooling comprising:
a pump;
a pump outlet line coupled with the pump to provide a pathway for a working fluid from the pump;
a pump inlet line coupled with the pump to provide a pathway for the working fluid to the pump;
a by-pass line with an internal burst plate, the by-pass line coupled with the pump outlet line and the pump inlet line, the burst plate to rupture at a selected pressure to prevent burst-related hazards in the microelectronic cooling system;
a heat exchanger coupled with the pump outlet line and pump inlet line; and
a microelectronic device thermally coupled with the heat exchanger.

41. A system according to claim 40, wherein the microelectronic device is an integrated circuit die and the heat exchanger is a microchannel heat exchanger used as part of a single-phase liquid cooling system.

42. A system according to claim 41, wherein the integrated circuit die is further coupled with memory.
